(19) United States
(12) Patent Application Publication
(10) Pub. No.: US 2012/0235670 A1
(43) Pub. Date: Sep. 20, 2012

(54) DRIVE SYSTEM FOR MICROMACHINED MAGNETIC FIELD SENSORS

(75) Inventors: Baris Cagdaser, Sunnyvale, CA (US); Derek Shaeffer, Redwood City, CA (US); Joe Seeger, Menlo Park, CA (US); Chiung C. Lo, Campbell, CA (US)

(73) Assignee: INVENSENSE, INC., Sunnyvale, CA (US)

(21) Appl. No.: 13/421,545

(22) Filed: Mar. 15, 2012

Related U.S. Application Data
(60) Provisional application No. 61/453,730, filed on Mar. 17, 2011.

(51) Int. Cl. G01R 35/00

(52) U.S. Cl. 324/202

(57) ABSTRACT

Described herein are systems, devices, and methods that provide a stable magnetometer. The magnetometer includes a drive element that facilitates flow of a drive current through a node and a sense element operable to detect a magnetic field operating on the drive current. To reduce offset in the detection of the magnetic field, a voltage detector, electrically coupled to the drive element through the node, determines a variation between a node voltage and a target voltage. The voltage detector facilitates suppression of the variation and thereby minimizes the offset in the sense element.

### CROSS REFERENCE TO RELATED APPLICATIONS

This patent application claims priority to U.S. provisional patent application Ser. No. 61/453,730 filed on Mar. 17, 2011.

### TECHNICAL FIELD

The subject application relates to regulation of offset and sensitivity in a magnetic field sensor.

### BACKGROUND

Lorentz force magnetometers generally include a drive element coupled to a sense element. The drive element facilitates a flow of current through a node. When immersed in a magnetic field, the sense element detects the resulting force acting on the flow of the current. Sensitivity of the magnetometer depends directly on the amplitude of the current. Voltage variations can be generated at the node where the drive element is electrically coupled to the sense element. These voltage variations often occur due to an internal drive element resistance interacting with the current, and can cause undesirable offsets.

### SUMMARY

The following presents a simplified summary of the claimed subject matter in order to provide a basic understanding of some aspects of the subject disclosure. This summary is not an extensive overview, and is not intended to identify key/critical elements or to delineate the scope of the claimed subject matter. Its sole purpose is to present some concepts in a simplified form as a prelude to the more detailed description that is presented later.

Described herein are systems, devices and methods that can reduce offset in a Lorentz force magnetometer. In one embodiment of the subject disclosure, a drive element facilitates flow of a drive current through a node and a sense element detects a magnetic field operating on the drive current. The drive current can be a bipolar pulse waveform with pulse width less than 50 percent of the drive period and its amplitude can be regulated. A voltage detector is electrically coupled to the drive element through the node. Through a feedback loop, the voltage detector determines a variation between a node voltage and a target voltage and facilitates suppression of the variation so that the detected voltage approximately matches the target voltage to minimize an offset in the sense element.

The following description and the annexed drawings set forth certain illustrative aspects of the disclosed subject matter. These aspects are indicative, however, of but a few of the various ways in which the principles of the principals of the innovation can be employed. The disclosed subject matter is intended to include all such aspects and their equivalents. Other advantages and distinctive features of the disclosed subject matter will become apparent from the following detailed description of the innovation when considered in conjunction with the drawings.

### BRIEF DESCRIPTION OF THE DRAWINGS

Non-limiting and non-exhaustive embodiments of the subject disclosure are described with reference to the following figures, wherein like reference numerals refer to like parts throughout the various views unless otherwise specified.

FIG. 1 is a schematic block diagram illustration of a magnetometer, according to an embodiment of the subject disclosure.

FIG. 2 is a schematic block diagram illustration of a magnetometer employing a system that facilitates correction of offset, according to an embodiment of the subject disclosure.

FIG. 3 is a schematic block diagram illustration of a magnetometer employing a feedback loop to facilitate correction of offset, a drive circuit to deliver drive current, and a coupling mechanism to couple the drive element node and the sense element, according to an embodiment of the subject disclosure.

FIG. 3a is a plot of the ratio of a bipolar pulse wave drive current's fundamental component to its direct current (DC) consumption as a function of the drive current pulse width, according to an embodiment of the subject disclosure.

FIG. 4 is a schematic block diagram illustration of a magnetometer employing a system that facilitates correction of offset and regulation of the drive current, according to an embodiment of the subject disclosure.

FIG. 5 is a schematic block diagram illustration of a magnetometer employing a feedback loop to facilitate correction of offset and a feedback loop to regulate drive current, according to an embodiment of the subject disclosure.

FIG. 6 is a schematic block diagram illustration of a magnetometer employing a differential drive system to facilitate correction of offset with a common mode feedback loop and a feedback loop to regulate drive current, according to an embodiment of the subject disclosure.

FIG. 7 is a process flow diagram of a method for minimizing offset in a magnetometer, according to an embodiment of the subject disclosure.

FIG. 8 is a process flow diagram of a method for sensing magnetic field with a magnetometer, according to an embodiment of the subject disclosure.

### DETAILED DESCRIPTION

In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

According to an aspect of the subject disclosure, described herein is a drive system for a dual-mode micromachined magnetometer, such as a Lorenz force magnetometer. The drive system reduces offset in the magnetometer and ensures that the magnetometer possesses a substantially constant sensitivity as environmental conditions change.

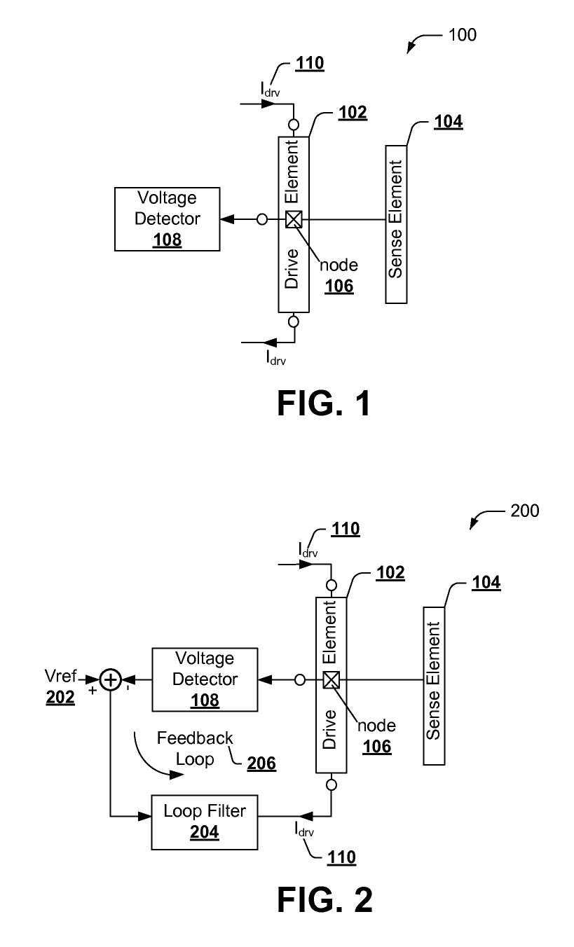

Referring now to FIG. 1, illustrated is a schematic block diagram of a magnetometer 100, according to an embodiment of the subject disclosure. The magnetometer 100 is an open loop system for analog magnetic sensing. Magnetometer 100 can be, for example, not limitation, a Lorentz force magnetometer constructed by micromachining processes. A Lorentz force magnetometer, for example, not limitation, can detect the Lorentz force acting on a current flowing through a drive element. The Lorentz force is proportional to the magnetic field and actuates a drive element. The Lorentz force, for example, not limitation, can be detected by measuring the displacement of a sense element which moves in response to the force acting on the drive element. Displacement can be measured by many ways known in the art, for example, not limitation, by using an electronic interface detecting capacitance change due to displacement.

Magnetometer 100 includes a drive element 102 coupled to a sense element 104 through a node 106. The node 106 is a coupling point for the drive element 102 and the sense element 104. For example, not limitation, the node 106 can be located substantially at the midpoint of the drive element. The drive element 102 facilitates the flow of drive current 110 through the node 106. The sense element 104 is operable to detect a magnetic field operating on the drive current 110. For example, not limitation, the drive current 110 can comprise of a bipolar pulse waveform with a pulse width less than 50 percent of the drive period. The drive current can also comprise other waveforms as would be familiar to one of ordinary skill in the art, for example, not limitation, sinusoidal or triangular.

Drive element 102 includes parasitic resistances that cause a voltage variation at the midpoint of the drive element 102 to vary with the drive current 110. This voltage variation can couple to the sense element 104 and be erroneously sensed as an offset.

The magnetometer also includes a voltage detector 108 that is electrically coupled to the drive element 102 through the node 106. The voltage detector 108 facilitates a determination of a variation between a node voltage and a target or reference voltage (Vref). The voltage detector 108 facilitates a suppression of the variation. Suppression of the variation can reduce offset in the sense element 104.

The suppression can be accomplished, for example, not limitation, through a feedback loop. As an example of a magnetometer 200 employing a feedback loop is shown in FIG. 2. The magnetometer 200 includes a drive element 102 coupled to a sense element 104 through a node 106. The feedback loop 206 of the magnetometer 200 is coupled to the voltage detector 108 and the drive element 102.

The feedback loop 206 can include a loop filter 204, by way of example, not limitation, that suppresses the variation between the voltage detected by the voltage detector 108 and a target or reference voltage (Vref) 202. The suppression of voltage variation through the loop filter 204 substantially eliminates offset due to the voltage variation.

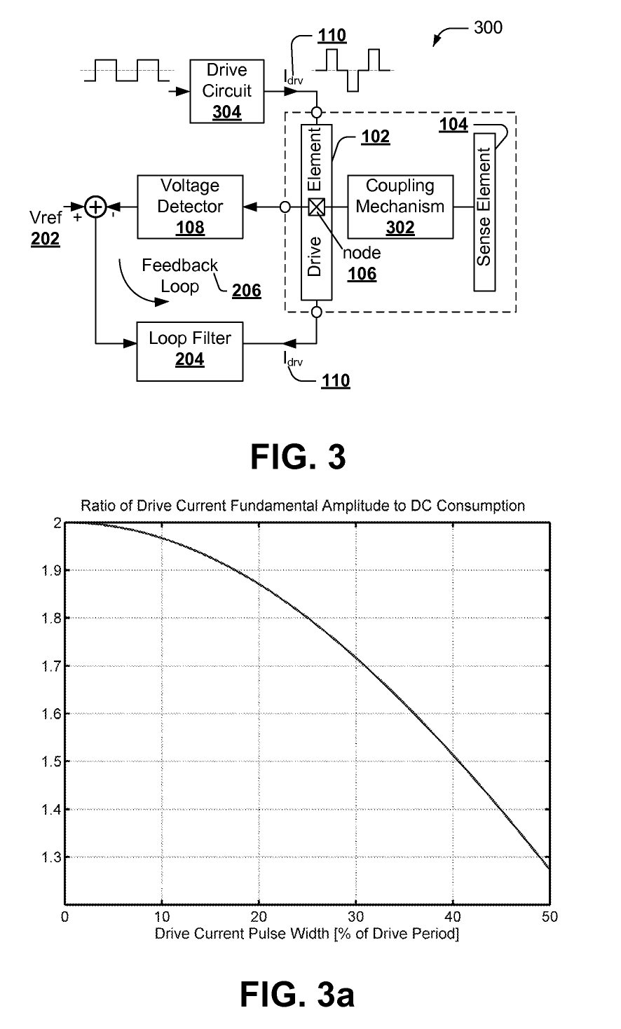

Referring now to FIG. 3, illustrated is an example embodiment of a magnetometer 300 employing a drive circuit 304 to regulate drive current 110. The magnetometer includes a drive element 102 coupled to a sense element 104 through a coupling mechanism 302. The drive element 102 can be coupled to the sense element 104, for example, not limitation, through the coupling mechanism 302 that is located substantially at the midpoint of the drive element 102. The coupling mechanism 302 can also be located substantially at an edge of the drive element 102 or at any other point in relation to the drive element 102. The drive circuit 304 supplies a drive current 110 to the drive element 102, and, through the coupling mechanism 302, the sense element 104 detects magnetic field acting on the drive current 110.

A drive circuit 304 generates the drive current 110 and applies the drive current 110 to the drive element 102. For example, not limitation, the drive circuit 304 can be coupled to a first terminal of the drive element 102. In an embodiment, the drive element 102 is coupled to the sense element 104 at a node 106 substantially at the midpoint of the drive element 102 through coupling mechanism 302. In another embodiment, the node 106 need not be located substantially at the midpoint of the drive element 102 and can be located at any point on the drive element. Coupling mechanism 302 allows the sense element 104 to sense any displacement of the drive element 102 due to Lorentz force acting on the drive current 110.

The voltage at the node 106 varies with the drive current 110 due to various factors, including parasitic resistance within the drive element 102, environmental conditions, and the like. This voltage variance can couple to the sense element 104 and be erroneously sensed as an offset.

To substantially eliminate offset due to the voltage variation, magnetometer 300 includes a drive system, including a voltage detector 108 (e.g., an AC voltage detector), and loop filter 204. The drive system can be referred to as a feedback loop 206. The drive system is a critical component of the coupling mechanism 302 for the drive element 102 and the sense element 104. The drive system creates a reliable virtual ground point at the coupling node 106, which prevents the magnetometer 300 from generating a large offset and offset shift. The offset and offset shift, for example and not limitation, can be due to manufacturing errors.

The voltage detector 108 is coupled to the drive element 102 (e.g., at the midpoint of the drive element) to detect voltage disturbances due to the drive element 102. Voltage detected by voltage detector 108 is compared to a target voltage, Vref 202. The difference between the voltage detected by voltage detector 108 and Vref 202 is fed into a loop filter 204. For example, not limitation, the loop filter 204 can be coupled to a second terminal of drive element 102.

The voltage at the node 106 of the drive element 102 can be driven to the reference or target voltage (Vref) 202 and held there by virtue of feedback action. Through suppression of variation in the voltage of the drive element 102, offsets due to voltage variation can be minimized and/or suppressed. Suppression of offsets can minimize drift associated with the offsets due to voltage.

Additionally, sensitivity of magnetometer 300 is proportional to the amplitude of the drive current 110. To provide a substantially constant sensitivity as environmental conditions change, the drive current 110 can have a constant amplitude. To increase sensitivity of magnetometer 300 and decrease noise, the drive current 110 can have a large amplitude. To provide low average power consumption, the ratio of drive current's 110 fundamental amplitude to its direct current (DC) consumption can be increased.

In an embodiment, the drive circuit 304 can increase the ratio of the drive current 110 fundamental amplitude to DC current consumption by employing a reduced pulse width bipolar pulse waveform drive current 110. By increasing the ratio of drive current's 110 fundamental amplitude to its DC current consumption, the drive circuit 304 can provide a larger drive current for the same power consumption. From a pulse width of 50 percent of the drive period to 25 percent of the drive period, drive circuit 304 can provide 50 percent or more fundamental drive current amplitude for the same DC consumption as shown in FIG. 3a. For example, not limitation, amplitude and pulse width trim can be employed to optimize the power consumption.

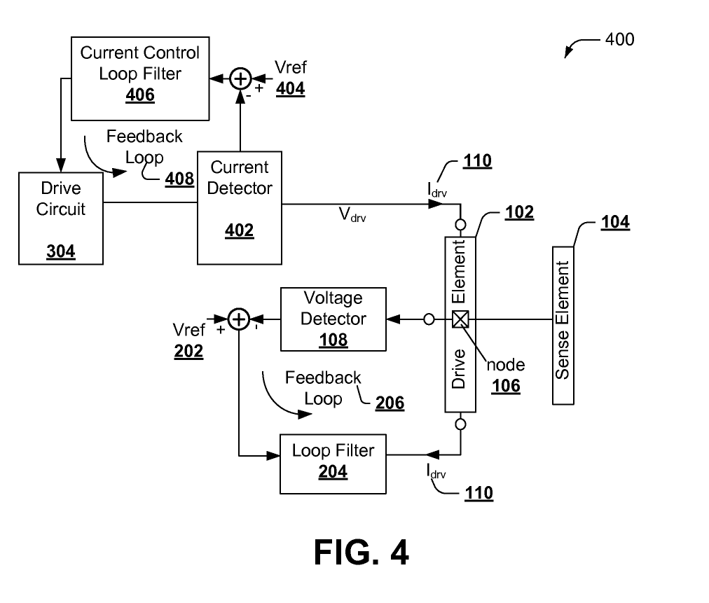

Sensitivity variation can be reduced by suppressing variation in the drive current 110. The suppression of variation in the drive current 110 can be accomplished, for example, not limitation, through a second feedback loop. As example of a magnetometer 400 employing a first feedback loop 206 to suppress voltage variation and a second feedback loop 408 to suppress variation in the drive current 110 is shown in FIG. 4. The magnetometer 400 includes a drive element 102 coupled to a sense element 104 through a node 106. The drive element 102 is supplied with the drive current 110 through a drive circuit 304. Regulation of the drive current 110 can provide a substantially constant drive current 110. For example and not limitation, the drive current 110 can be regulated through the second feedback loop 408. A current detector 402 can be coupled to the drive circuit 304 to sense the drive current 110 and produce a voltage proportional to the drive current 110. Through the second feedback loop 408, the voltage produced by the current detector 402 can be compared to a target or reference voltage (Vref) 404, which can be different from Vref 202. The second feedback loop 408 can drive the voltage at the current detector 402 to Vref 404, substantially eliminating variation and ensuring a substantially constant drive current 110.

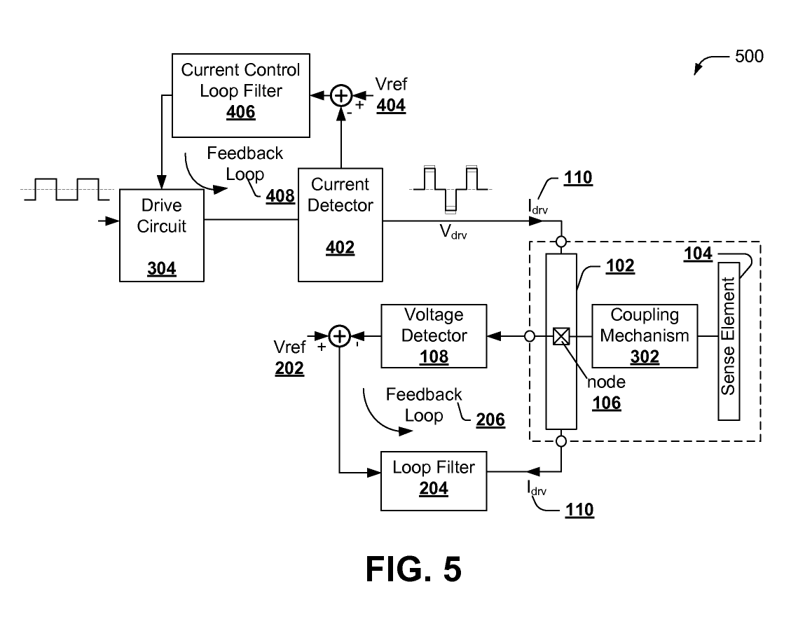

Referring now to FIG. 5, illustrated is an example embodiment of a magnetometer 500 that regulates the amplitude of the drive current 110. The amplitude of the drive current 110 is regulated through the second feedback loop 408. The second feedback loop 408 allows regulation of sensitivity of the sense element 104 by providing a substantially constant drive current 110 amplitude. By providing a drive current 110 with a substantially constant amplitude, undesirable qualities, such as temperature variation of sensitivity, can be prevented. Further, providing a drive current 110 with a constant amplitude can also can improve manufacturability by mitigating sensitivity variation due to contact resistance.

The second feedback loop 408 includes a current detector 402 coupled to the drive circuit 304 output. Current detector 402 produces a voltage proportional to the drive current 304. The voltage produced by the current detector 402 is compared against a target voltage, Vref 404. The difference between the voltage produced by the current detector 402 and Vref 404 is fed back to the drive circuit 304 through a current control loop filter 406. Through feedback action, the drive current 110 is regulated to have a substantially constant amplitude over voltage, temperature and/or process variation. The substantially constant amplitude of the drive current 110 is beneficial to stabilize the gain of the sense element 104.

The sense element 104 detects the Lorenz force generated for each unit of applied magnetic field, which is proportional to the amplitude of the drive current 110. Regulating the drive current 110 can stabilize the gain of the sense element 104 because the Lorentz force generated for a unit of applied magnetic field is proportional to the drive current 110 amplitude.

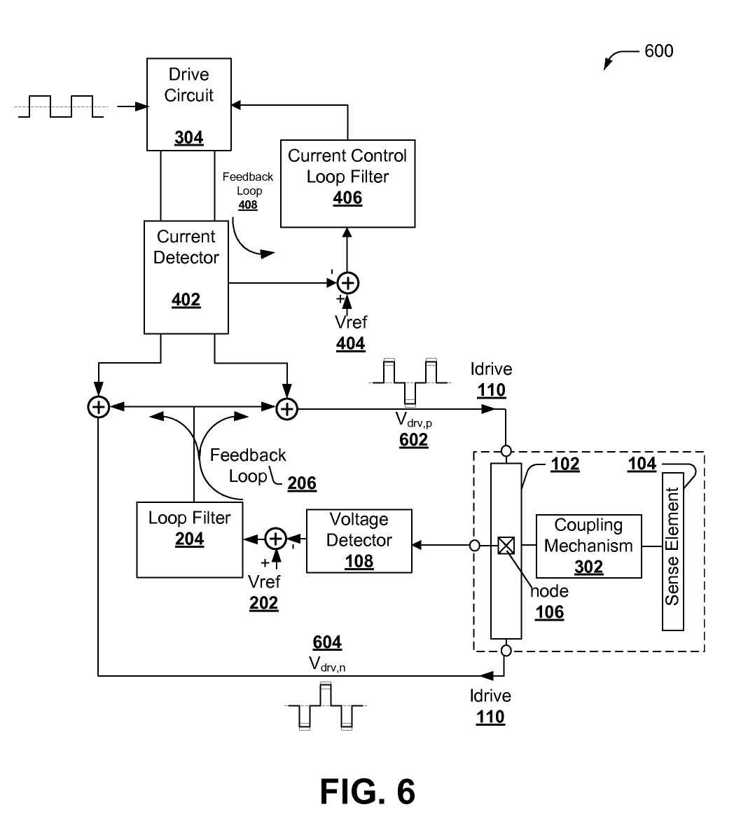

Referring now to FIG. 6, illustrated is an example embodiment of a magnetometer 600 employing a differential drive system. The drive element 102 of magnetometer 600 is operable to facilitate a differential flow of current.

The drive system employed by magnetometer 600 drives opposite ends of drive element 102 differentially. The voltage at the node 106 of drive element 102 is monitored by a voltage detector 108. The voltage at node 106 of the drive element 102 (e.g., at the midpoint of the drive element 102) is compared to a target reference voltage, Vref 202 The difference between the voltage detected by the voltage detector 108 and Vref 202 is applied to loop filter 204. Loop filter 204 can actuate a common-mode feedback to the drive element 102 voltage (Vdrv,p 602 and Vdrv,n 604). Through feedback action, the voltage of node 106 at the drive element 102 can be held substantially constant. Holding the voltage of node 106 of the drive element 102 constant can prevent offsets that would otherwise arise due to voltage variation.

The drive system employed by magnetometer 600 also employs a second feedback loop 408 to regulate the amount of current flowing from the drive circuit 304 to the drive element 102. In an embodiment, second feedback loop 408 is optional.

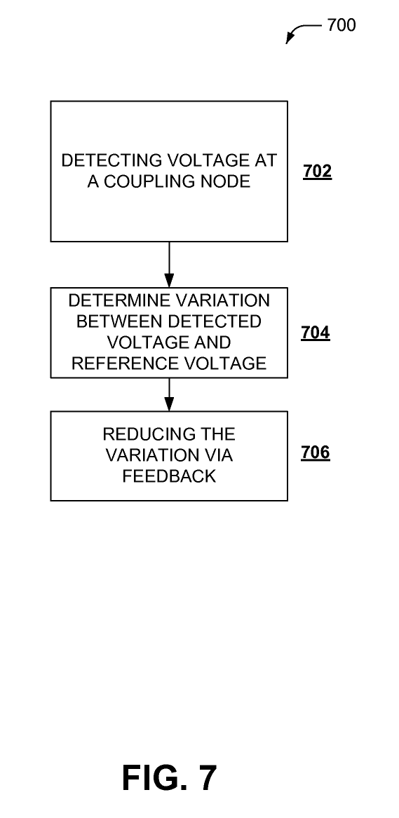

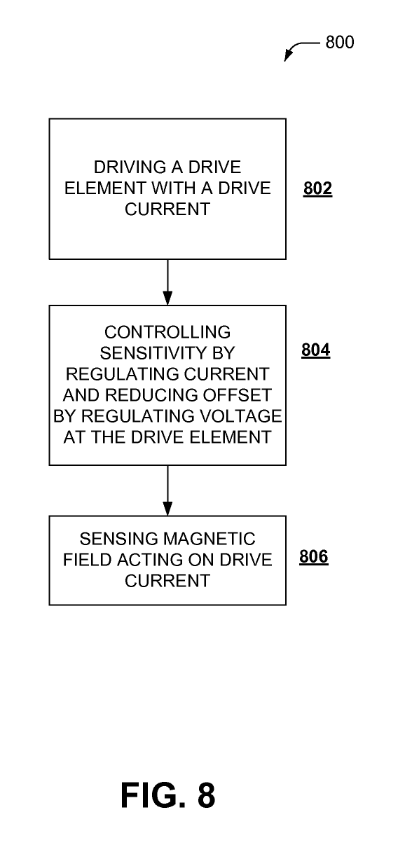

FIGS. 7 and 8 show examples of methods illustrated as flow diagrams. For simplicity of explanation, the methods are depicted and described as series of acts. However, the methods are not limited by the acts illustrated or by the order of acts. For example, acts can occur in various orders and/or concurrently, and with other acts not presented and described herein. Furthermore, not all illustrated acts may be required to implement the methods. Additionally, it should be further appreciated that the methods can be implemented on an article of manufacture (e.g., a magnetometer) to facilitate transporting and transferring the methods.

Referring now to FIG. 7, illustrated is a method for minimizing offset in a magnetometer. The method begins at element 702 where a voltage is detected at a coupling node. For example, the voltage detected can be a voltage detected by a voltage detector, coupled to a node of the drive element of a magnetometer (e.g., at the midpoint of the drive element).

At element 704, a variation can be determined between the voltage detected at the node and a reference voltage. The variation can be due to a disturbance to the drive element. For example, not limitation, the voltage disturbances can be due to parasitic resistances in the drive element that cause voltage to vary with the drive current. This voltage variance can couple to a sense element coupled to the drive element and be erroneously sensed as offset.

At element 706, the variation can be reduced via feedback. The difference between the voltage sensed at the node and Vref can be, for example, not limitation, fed into a loop filter. The loop filter can drive the voltage of the drive element to Vref and hold the node voltage of the drive element at Vref, substantially eliminating variation in the voltage of the drive element. Regulating the voltage can minimize drift associated with the offsets due to voltage.

Referring now to FIG. 8, illustrated is a method for sensing a magnetic field acting. The method begins at element 802 where a drive element is driven with a drive current. The drive current can be, for example, not limitation, be generated by a drive circuit. A bipolar pulse wave drive current can have a pulse width less than 50 percent of the drive period. The drive current can also comprise of other waveforms as would be familiar to one of ordinary skill in the art, for example, not limitation, sinusoidal or triangular.

At element 804, sensitivity in the magnetometer can be controlled by regulating the drive current. The drive current can be regulated by sensing the drive current with a current detector. The current detector can output a voltage proportional to the drive current. The voltage output by the current detector is compared to a second reference voltage, which can be different from the reference voltage used for voltage regulation. The drive circuit can be adjusted based on the voltage difference. Adjusting the drive circuit can compensate for variations in the drive element and substantially reduce the variation in the drive current.

Alternatively, current detector can output a current which can be compared to a reference current. The current difference can be used for adjusting the drive circuit.

At element 804, offset in the magnetometer can be reduced by regulating the node voltage of a drive element. The voltage can be regulated by sensing the voltage of the drive element and comparing the sensed voltage to a reference voltage, and eliminating the difference through a feedback loop. The node voltage of the drive element can be driven to the reference voltage and held at the reference voltage. Reducing the variation in the node voltage of the drive element can substantially eliminate offset and erroneous detections of magnetic field.

For the avoidance of doubt, the subject matter described herein is not limited by anything referred to as an examples. Such examples are not necessarily to be construed as preferred or advantageous over other aspects or designs, nor are the examples meant to preclude equivalent exemplary structures and techniques known to those of ordinary skill in the art. Furthermore, to the extent that the terms “includes,” “has,” “contains,” and other similar words are used in either the detailed description or the claims, for the avoidance of doubt, such terms are intended to be inclusive in a manner similar to the term “comprising” as an open transition word without precluding any additional or other elements.

The subject matter as described above includes various aspects. However, it should be appreciated that it is not possible to describe every conceivable component or method for purposes of describing these aspects. One of ordinary skill in the art will recognize that further combinations or permutations may be possible. Accordingly, all implementations of the aspects described herein are intended to embrace the scope and spirit of the following claims.

What is claimed is:

1. A system, comprising:
a drive element that facilitates flow of a drive current through a node;
a sense element operable to detect a magnetic field operating on the drive current; and
a voltage detector electrically coupled to the drive element through the node, wherein the voltage detector determines a variation between a node voltage and a target voltage and facilitates suppression of the variation to minimize an offset in the sense element.

2. The system of claim 1, wherein the node is a coupling point for the drive element and the sense element.

3. The system of claim 1, wherein the node is located substantially at a midpoint of the drive element.

4. The system of claim 1, further comprising a feedback loop coupled to the voltage detector and the drive element that facilitates the suppression of the variation.

5. The system of claim 4, wherein the drive element is operable to facilitate differential flow of current.

6. The system of claim 5, wherein the feedback loop effectuates common-mode feedback to suppress the variation.

7. The system of claim 1, wherein a pulse width of the drive current is less than 50 percent of the drive period.

8. The system of claim 1 further comprising:
a current detector electrically coupled to the drive element, wherein the current detector detects the drive current; and
a second loop filter electrically coupled to the current detector and the drive element, wherein the second loop filter is operable to adjust the drive current.

9. The system of claim 8, wherein the second loop filter suppresses variation in the drive current.

10. A device, comprising:
a drive element that facilitates flow of a drive current with a drive pulse width of less than 50 percent of the drive period through a node;
a sense element operable to detect a magnetic field operating on the drive current; and
a drive circuit electrically coupled to the drive element, wherein the drive circuit provides the drive element with the drive current.

11. The device of claim 10, further comprising:
a voltage detector electrically coupled to the drive element through the node, wherein the detector detects a node voltage and determines a variation between the node voltage and a target voltage; and
a feedback loop electrically coupled to the drive element and the voltage detector, wherein the feedback loop suppresses the variation.

12. The device of claim 11, wherein the feedback loop comprises a loop filter that suppresses the variation.

13. The device of claim 10, wherein the node is a coupling point for the drive element and the sense element.

14. The device of claim 10, wherein the node is located substantially at a midpoint of the drive element.

15. A method, comprising:
reducing a magnetic sensor offset, comprising:
detecting a voltage at a node coupling a drive element of a magnetic sensor and a sense element of the magnetic sensor;
determining a variation between the detected voltage and a reference voltage; and
reducing the variation in the detected voltage by using a feedback loop so that the detected voltage approximately matches the reference voltage; and
sensing a magnetic field acting on the drive element at the sense element.

16. The method of claim 15, further comprising driving the drive element with a drive current.

17. The method of claim 16, further comprising:
detecting an amplitude of the drive current;
determining a second variation between the detected amplitude and a reference amplitude; and
regulating the drive current to substantially eliminate the second variation.

18. The method of claim 16, wherein the driving further comprises driving the drive element with a drive current with a drive pulse width less than 50 percent of the drive period.

19. The method of claim 16, further comprising facilitating a differential flow of current through the drive element.

20. The method of claim 19, wherein the reducing further comprises reducing the variation in the detected voltage by using a feedback loop effectuating common-mode feedback.
